(19) United States
(12) Patent Application Publication
(10) Pub. No.: US 2010/0224918 A1
(43) Pub. Date: Sep. 9, 2010

(54) Semiconductor devices and CMOS image sensors having a shielding wall, electronic apparatuses having the same and methods of fabricating the same

(75) Inventor: Eun-Gyu Lee, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/659,367

(22) Filed: Mar. 5, 2010

(30) Foreign Application Priority Data
Mar. 9, 2009 (KR) 10-2009-0019962

(51) Int. Cl. H01L 29/06; H01L 27/146

(52) U.S. Cl. 257/291; 257/506; 257/E29.02; 257/E27.133

(57) ABSTRACT

Semiconductor devices, CMOS image sensors, electronic apparatuses and methods of fabricating the same are provided, the semiconductor devices include a semiconductor substrate having stopper layers and interlayer insulating layers which are alternately stacked, wherein interfaces between the stopper layers and the interlayer insulating layers are formed in a horizontal direction. A first conductor and a second conductor each vertically extend through the interlayer insulating layers and the stopper layers. An insulating shielding wall is formed between the first and second conductors. The insulating shielding wall vertically extends through the interfaces between the stopper layers and the interlayer insulating layers such that at least one of the interfaces is divided into separate sections.

### CROSS-REFERENCE TO RELATED APPLICATIONS

This application claims the benefit of priority under 35 U.S.C. §119 from Korean Patent Application No. 10-2009-0019962, filed on Mar. 9, 2009, the contents of which are hereby incorporated herein by reference in their entirety.

### BACKGROUND

1. Field

Example embodiments of the general inventive concepts provide semiconductor devices and CMOS image sensors having a shielding wall, methods of fabricating the same, and electronic apparatuses having the same. More particularly, the semiconductor devices may include a via pad, or an interconnection formed of metal, in particular, copper.

2. Description of Related Art

One of the largest changes in semiconductor device technology is the development and increased performance of conductors that exhibit a decrease in resistance as patterns become smaller. Due to such conductors, interconnections of semiconductor devices may be formed using metal, particularly, a metal with low resistance, rather than silicon. As a low resistance metal, copper is attracting attention but it is difficult to use copper due to electro-migration.

### SUMMARY

Example embodiments provide semiconductor devices and CMOS image sensors having a shielding wall, methods of fabricating the same, and electronic apparatuses having the same. More particularly, the semiconductor devices may include a via pad, or an interconnection formed of metal, in particular, copper.

An example embodiment of the general inventive concepts provides a semiconductor device including a shielding wall. Another example embodiment of the general inventive concepts provides a CMOS sensor including a shielding wall.

Other example embodiments of the general inventive concepts provide an electronic system including the semiconductor device.

Yet other example embodiments of the general inventive concepts provide a method of fabricating a semiconductor device in which the lengths of interfaces of insulating layers formed between conductors are increased.

Still yet another example embodiments of the general inventive concepts provide a method of fabricating the complementary metal-oxide-semiconductor (CMOS) image sensor.

An example embodiment is directed to a semiconductor device. The semiconductor device includes a semiconductor substrate having stopper layers and interlayer insulating layers that are alternately stacked, wherein interfaces between the stopper layers and the interlayer insulating layers are formed in a horizontal direction. The semiconductor device includes a first conductor and a second conductor that are formed to vertically penetrate (or extend through) the interlayer insulating layers and the stopper layers, and an insulating shielding wall formed between the first and second conductors. The insulating shielding wall is configured to stop extension of the interfaces. That is, the insulating shielding wall may vertically extend through the interfaces between the stopper layers and the interlayer insulating layers such that the interfaces are divided into separate sections in the horizontal direction.

Another example embodiment is directed to a CMOS image sensor. The CMOS image sensor includes at least two photo detecting portions, at least one voltage supply portion, at least two gate structures, an insulating material between the voltage supply portion and at least one of the gate structure, and at least one shielding wall in the insulating material.

Still other example embodiments are directed to a CMOS image sensor. The CMOS image sensor includes a first active pixel sensor and a second pixel sensor, the first active pixel sensor including a first photo detecting portion, a first voltage supply portion, a plurality of first gate structures, and a first insulating material between the first voltage supply portion and the first gate structure. The second active pixel sensor includes a second photo detecting portion, a second voltage supply portion, a plurality of second gate structures, and a second insulating material between the second voltage supply portion and the second gate structure. The CMOS image sensor includes a first shielding wall between the first and second active pixel sensors.

Other example embodiments are directed to an electronic apparatus. The electronic apparatus includes a controller to control electronic signals, a storage unit electrically connected to the controller, an input unit electrically connected to the controller to receive first signals, and an output unit electrically connected to the controller to transmit second signals, wherein one of the elements includes a semiconductor device. The semiconductor device includes a semiconductor substrate having stopper layers and interlayer insulating layers that are alternately stacked, wherein interfaces between the stopper layers and the interlayer insulating layers are formed in a horizontal direction. A first conductor and a second conductor are formed to vertically penetrate (or extend through) the interlayer insulating layers and the stopper layers, and an insulating shielding wall is formed between the first and second conductors. The insulating shielding wall is configured to stop extension of the interfaces. That is, the insulating shielding wall may vertically extend through the interfaces between the stopper layers and the interlayer insulating layers such that the interfaces are divided into separate sections in the horizontal direction.

Yet other example embodiments are directed to a method of fabricating a semiconductor device. The method of fabricating a semiconductor device includes forming a first stopper layer on a semiconductor substrate, forming a first interlayer insulating layer on the first stopper layer, forming a second stopper layer on the first interlayer insulating layer, forming a second interlayer insulating layer on the second stopper layer. A lower portion of a first conductor structure and a lower portion of a second conductor structure may vertically penetrate (or extend through) the first and second stopper layers and interlayer insulating layers. The method includes forming a lower portion of a shielding wall between the lower portion of the first conductor structure and the lower portion of the second conductor structure, the lower portion of the shielding wall vertically penetrating (or extending through) the first and second stopper layers and interlayer insulating layers.

Still yet another example embodiment is directed to a method of fabricating a CMOS image sensor. The method of fabricating a CMOS image sensor includes forming at least two photo detecting portions, forming at least one voltage supply portion, forming at least two gate structures, forming an insulating material between the voltage supply portion and at least one of the gate structures, and at least one shielding wall in the insulating material.

Still yet other example embodiments are directed to a method of fabricating a CMOS image sensor. The method of fabricating a CMOS image sensor includes forming a first active pixel sensor and a second pixel sensor. Forming the first active pixel sensor includes forming a first photo detecting portion, forming a first voltage supply portion, forming a plurality of first gate structures, and forming a first insulating material between the first voltage supply portion and the first gate structure. Forming the second active pixel sensor includes forming a second photo detecting portion, forming a second voltage supply portion, forming a plurality of second gate structures, and forming a second insulating material between the second voltage supply portion and the second gate structures, and forming a first shielding wall between the active pixel sensors.

Further example embodiments are directed to a method of fabricating an electronic apparatus. The method of fabricating an electronic apparatus includes forming a controller configured to control electronic signals, forming a storage unit electrically connected to the controller, and forming an input unit electrically connected to the controller. The input unit is configured to receive a plurality of first electronic signals. The method further includes forming an output unit electrically connected to the controller. The output unit is configured to transmit a plurality of second electronic signals. At least one of the controller, the storage unit, the input unit and the output unit is formed with a semiconductor device or CMOS image sensor according to the above example embodiments.

### BRIEF DESCRIPTION OF THE DRAWINGS

Example embodiments are described in further detail below with reference to the accompanying drawings. It should be understood that various aspects of the drawings may have been exaggerated for clarity.

FIG. 1 is a longitudinal sectional view of a part of a semiconductor device according to an example embodiment.

FIGS. 2A and 2C are transverse sectional views of the semiconductor device shown in FIG. 1.

FIGS. 3 to 5 are longitudinal sectional views of semiconductor devices according to other example embodiments.

FIGS. 6 and 7 are schematic layouts of complementary metal-oxide-semiconductor (CMOS) image sensors according to application further example embodiments.

FIGS. 8A to 8D are longitudinal sectional views schematically illustrating a method of fabricating a semiconductor device according to yet other example embodiments.

FIGS. 9A and 9B are longitudinal sectional views schematically illustrating a method of fabricating a semiconductor device according to still other example embodiments.

FIGS. 10A and 10B are longitudinal sectional views schematically illustrating a method of fabricating a semiconductor device according to still yet other example embodiments.

FIG. 11 is a block diagram illustrating an electronic apparatus including the semiconductor device or the CMOS image sensor according to still yet another example embodiment of the general inventive concepts.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an active region illustrated as a rectangle may have rounded or curved features at its edges. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

In this specification, the term “via” indicates a pillar-type conductive pattern that transfers electrical signals in a vertical direction, the term “interconnection” indicates a line-type conductive pattern that transfers electrical signals in a horizontal direction, and the term “pad” indicates an island-type conductive pattern that electrically connects a via to another via or a via to an interconnection.

Example embodiments provide semiconductor devices and CMOS image sensors having a shielding wall, methods of fabricating the same, and electronic apparatuses having the same. More particularly, the semiconductor devices may include a via pad, or an interconnection formed of metal, in particular, copper.

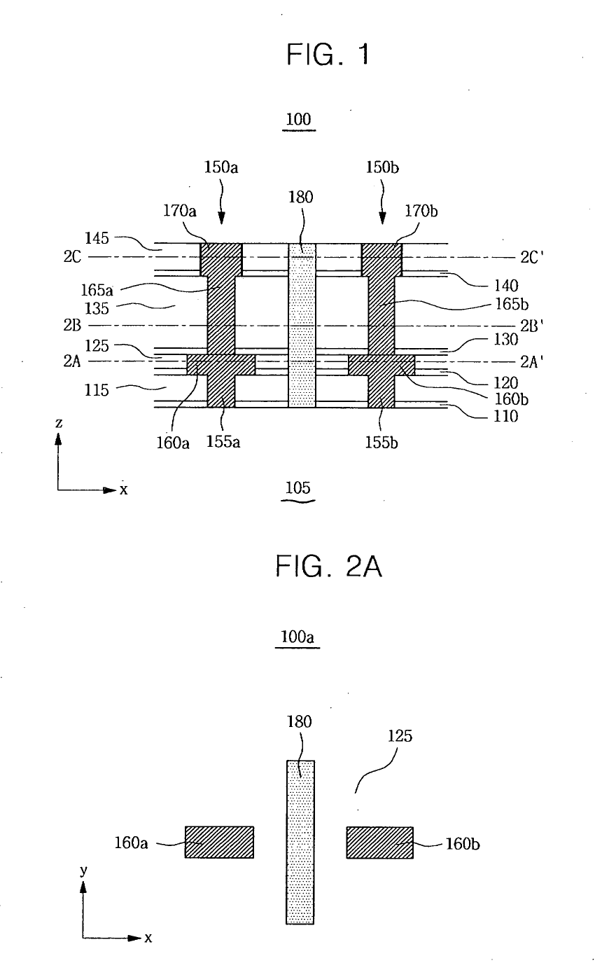

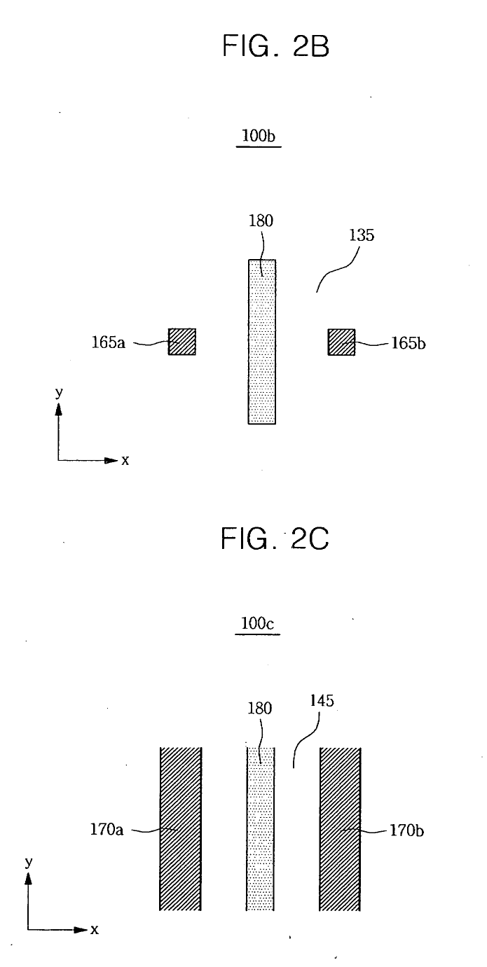

FIG. 1 is a longitudinal sectional view of a part of a semiconductor device according to an example embodiment of the general inventive concepts, and FIGS. 2A and 2C are transverse sectional views of the semiconductor device shown in FIG. 1.

Referring to FIG. 1, a semiconductor device 100 includes interlayer insulating layers 115, 125, 135 and 145, and stopper layers 110, 120, 130 and 140, formed on a substrate 105. The semiconductor device 100 includes a first conductor 150a, a second conductor 150b, and a shielding wall 180 disposed between the first conductor 150a and the second conductor 150b. The first conductor 150a, the second conductor 150b, and the shielding wall 180 may be formed to vertically penetrate (or extend through) the interlayer insulating layers 115, 125, 135 and 145 and the stopper layers 110, 120, 130 and 140.

The first conductor 150a may include at least one of vias 155a and 165a, a pad 160a, and an interconnection 170a. The second conductor 150b may include at least one of vias 155b and 165b, a pad 160b and an interconnection 170b. In the drawing, each of the first and second conductors 150a and 150b includes all of the vias 155a, 155b, 165a and 165b, the pads 160a and 160b, and the interconnections 170a and 170b, respectively. The first and second conductors 150a and 150b may be formed of metal, and in particular, may include copper.

Each of the interlayer insulating layers 115, 125, 135 and 145 and each of the stopper layers 110, 120, 130 and 140 may be paired with each other and stacked, and the pairs may be stacked in multiple layers. For example, the interlayer insulating layer 115 may be paired with the stopper layer 110, and the interlayer insulating layer 125 may be paired with the stopper layer 120. The stacked interlayer insulating layers 115, 125, 135 and 145 and the stacked stopper layers 110, 120, 130 and 140 include interfaces extending in a horizontal direction (along the x-axis). Upper surfaces of the interlayer insulating layers 115, 125, 135 and 145 may be formed in the same plane as upper surfaces of the respective components of the first and second conductors 150a and 150b. The interlayer insulating layers 115, 125, 135 and 145 may be formed of silicon oxide containing a substantially small amount of impurities including boron (B), phosphorous (P), fluorine (F), carbon (C), hydrogen (H) and the like. For example, the silicon oxide may include boron silicate glass (BSG), phosphorous silicate glass (PSG), boron phosphorous silicate glass (BPSG), silicon oxy fluoride (SiOF), silicon carbonic hydro oxide (SiCHO), tetra-ethyl-ortho-silicate (TEOS) and similar compounds. In addition to the impurities, germanium (Ge), nitrogen (N) and like elements may be included. The interlayer insulating layers 115, 125, 135 and 145 may be formed by various methods (e.g., a coating method or a deposition method using heat or plasma).

Each of the stopper layers 110, 120, 130 and 140 may be formed of a harder material than the interlayer insulating layers 115, 125, 135 and 145, or a material having a dry and/or wet etch selectivity with respect to the interlayer insulating layers 115, 125, 135 and 145. Lower surfaces of the stopper layers 110, 120, 130 and 140 may be form on the same plane as the upper surfaces of the respective components of the first and second conductors 150a and 150b. The interlayer insulating layers 115, 125, 135 and 145 may be formed thicker than the stopper layers 110, 120, 130 and 140. The stopper layers 110, 120, 130 and 140 may be formed of an insulating material harder than a silicon oxide layer. For example, the stopper layers 110, 120, 130 and 140 may be silicon nitride layers or silicon oxynitride layers.

The shielding wall 180 may be disposed between the first conductor 150a and the second conductor 150b. In the drawing, the shielding wall 180 is formed in the middle between the first conductor 150a and the second conductor 150b, but is not limited thereto. The shielding wall 180 may prevent the interfaces between the interlayer insulating layers 115, 125, 135 and 145 and the stopper layers 110, 120, 130 and 140 formed between the first conductor 150a and the second conductor 150b from extending in the horizontal direction. In other words, the interfaces between the interlayer insulating layers 115, 125, 135 and 145 and the stopper layers 110, 120, 130 and 140 may stop extending (or be divided into separate sections) in the horizontal direction at the shielding wall 180. Interfaces between the shielding wall 180 and the interlayer insulating layers 115, 125, 135 and 145 and interfaces between the shielding wall 180 and the stopper layers 110, 120, 130 and 140 may be formed in a vertical direction (along the z-axis). The shielding wall 180 may be formed of an insulating material. For example, the shielding wall 180 may be formed of silicon oxide, silicon nitride, silicon oxynitride or other insulating materials. The other insulating material may include oxide (e.g., hafnium oxide (HfO) and alumina (Al₂O₃)) or silicon oxide containing a small amount of impurities including boron (B), phosphorous (P), fluorine (F) and the like). In this example embodiment, one insulator may be formed vertically and deeply (or extend in the vertical direction to the same length) as the shielding wall 180. In other words, the shielding wall 180 may be formed of one insulating material. However, the shielding wall 180 may be formed of various materials (i.e., two or more materials), which will be described later.

Referring to FIG. 2A, a semiconductor device 100a according to example embodiments includes a shielding wall 180 formed between a pad 160a of a first conductor 150a and a pad 160b of a second conductor 150b. The shielding wall 180 may be formed to be longer than one side (for example, in the direction extending along the y-axis) of the pad 160a of the first conductor 150a and the pad 160b of the second conductor 150b. Even if the pads 160a and 160b are formed in a shape other than a quadrilateral shape (e.g., in a circular, oval, or polygonal shape), the length of the shielding wall 180 in the longer direction (for example, the direction extending along the y-axis) may be larger than the lengths of the pads 160a and 160b along the same direction. Even if the pads 160a and 160b are formed in the shape of a vertical bar, the vertical length of the shielding wall 180 may be longer than that of the pads 160a and 160b along the same direction.

Referring to FIG. 2B, a semiconductor device 100b according to example embodiments includes a shielding wall 180 formed between a via 165a of a first conductor 150a and a via 165b of a second conductor 150b. The length of the shielding wall 180 in the longer direction (for example, the direction extending along the y-axis) may be larger than the length of the via 165a of the first conductor 150a in the longer direction and the length of the via 165b of the second conductor 150b in the longer direction. Even if the vias 165a and 165b are formed in a circular, oval or polygonal shape, the length of the shielding wall 180 in the longer direction may be larger than the lengths of the vias 165a and 165b in their longer directions. Even if the vias 165a and 165b are formed in a shape that is longer in one direction than another direction (e.g., a vertical bar shape), the vertical length of the shielding wall 180 may be longer than those of the vias 165a and 165b.

Referring to FIG. 2C, a semiconductor device 100c according to example embodiments includes a shielding wall 180 formed between an interconnection 170a of a first conductor 150a and an interconnection 170b of a second conductor 150b. In the drawing, the interconnections 170a and 170b have a larger width than the shielding wall 180, but the widths of the interconnections 170a and 170b and the width of the shielding wall 180 may have no relation with each other.

In this example embodiment, it is assumed that components performing the same function among the components of the first and second conductors 150a and 150b are formed on the same plane. This is because it is assumed that the two conductors 150a and 150b have the same constitution and shape to aid in understanding the inventive concepts. The two conductors 150a and 150b may be formed to have different constitutions and shapes.

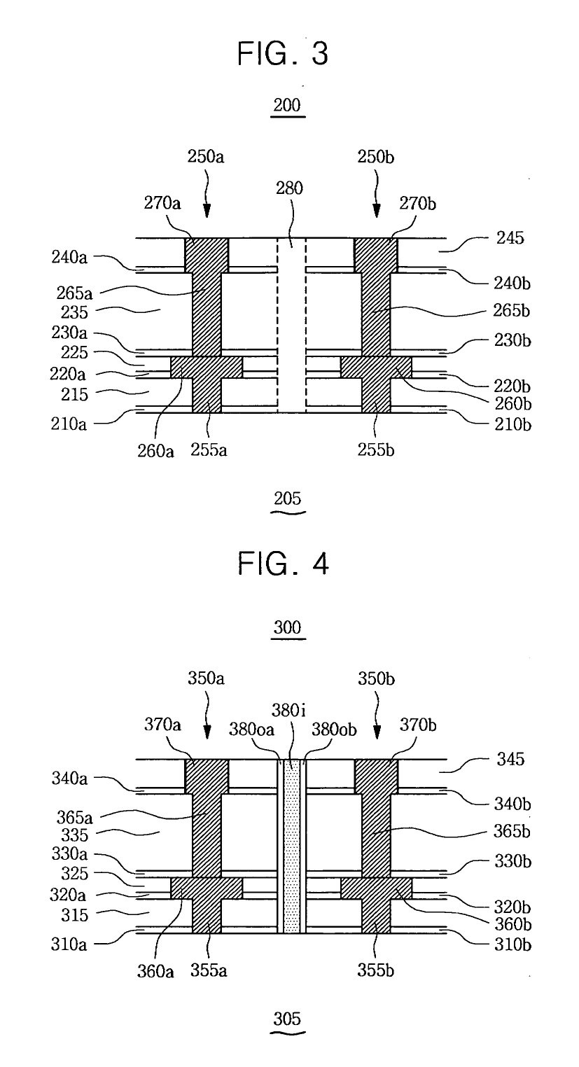

FIGS. 3 to 5 are longitudinal sectional views of semiconductor devices according to other example embodiments.

Referring to FIG. 3, a semiconductor device 200 according to a second example embodiment includes interlayer insulating layers 215, 225, 235 and 245, stopper layers 210a, 220a, 230a and 240a in a first area, stopper layers 210b, 220b, 230b and 240b in a second area, a first conductor 270a formed in the first area, and a second conductor 270b formed in the second area. The stopper layers 210a, 220a, 230a and 240a in the first area and the stopper layers 210b, 220b, 230b and 240b in the second area are spaced apart from each other in the same planes. The stopper layers 210a, 220a, 230a and 240a in the first area are adjacent to the first conductor 270a, and the stopper layers 210b, 220b, 230b and 240b in the second area are adjacent to the second conductor 270b. In a space between the stopper layers 210a, 220a, 230a and 240a in the first area and the stopper layers 210b, 220b, 230b and 240b in the second area, a virtual shielding wall 280 may be formed. The interlayer insulating layers 215, 225, 235 and 245 may extend to the virtual shielding wall 280. In the drawing, all the stopper layers 210a, 220a, 230a and 240a in the first area and all the stopper layers 210b, 220b, 230b and 240b in the second area are formed in multiple layers. However, this is only an example, and one of the stopper layers 210a, 220a, 230a and 240a in the first area and one of the stopper layers 210b, 220b, 230b and 240b in the second area may be spaced apart from each other in the corresponding one layer only.

FIG. 3 shows that when the shielding wall 280 is formed of the same material as the interlayer insulating layers 215, 225, 235 and 245, there may be no interfaces between the shielding wall 280 and the interlayer insulating layers 215, 225, 235 and 245.

Referring to FIG. 4, a semiconductor device 300 according to a third example embodiment includes interlayer insulating layers 315, 325, 335 and 345, stopper layers 310a, 320a, 330a and 340a in a first area, stopper layers 310b, 320b, 330b and 340b in a second area, a first conductor 370a formed in the first area, a second conductor 370b formed in the second area, and a shielding wall 380 formed between the first conductor 370a and the second conductor 370b. The shielding wall 380 includes outer shielding walls 380oa and 380ob and an inner shielding wall 380i. The outer shielding walls 380oa and 380ob may be formed to surround the inner shielding wall 380i.

One of the outer shielding walls 380oa and 380ob and the inner shielding wall 380i may be formed of a harder material than the interlayer insulating layers 315, 325, 335 and 345, and the other may be formed of the same material as the interlayer insulating layers 315, 325, 335 and 345. The material harder than the interlayer insulating layers 315, 325, 335 and 345 may be, for example, a material constituting the stopper layers 310, 320, 330 and 340. For example, the outer shielding walls 380oa and 380ob may be formed of silicon nitride, and the inner shielding wall 380i may be formed of silicon oxide.

The outer shielding walls 380oa and 380ob are separated in the longitudinal sectional view, but may be actually formed in a rim shape. In other words, the outer shielding walls 380oa and 380ob may have one body, or be integrally formed.

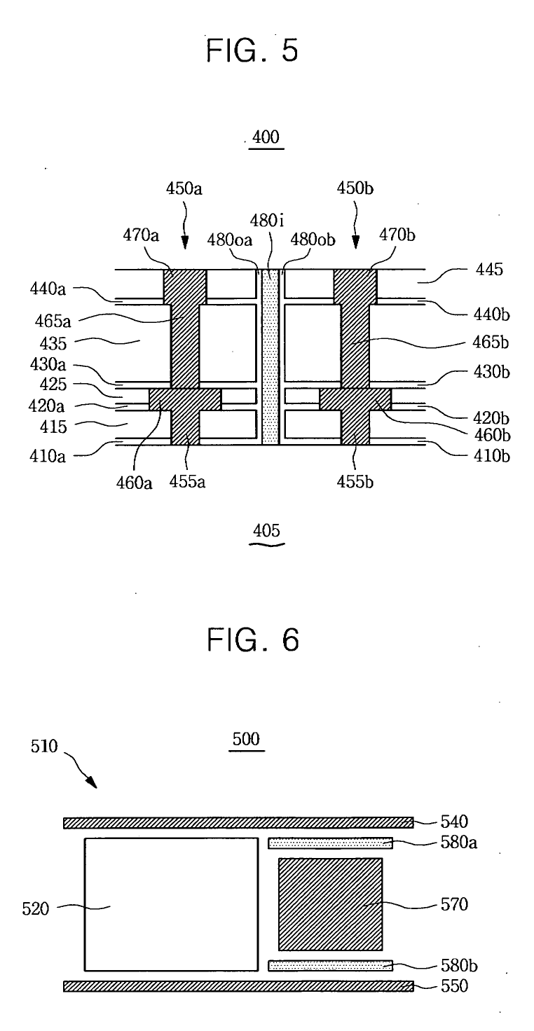

Referring to FIG. 5, a semiconductor device 400 according to a fourth example embodiment shows that outer shielding walls 480oa and 480ob may be formed of the same material as stopper layers 410, 420, 430 and 440, and an inner shielding wall 480i may be formed of the same material as the interlayer insulating layers 415, 425, 435 and 445 in the structure of the semiconductor device 300 shown in FIG. 4 according to the third example embodiment. In other words, interfaces between the outer shielding walls 480oa and 480ob and the stopper layers 410, 420, 430 and 440 may be removed.

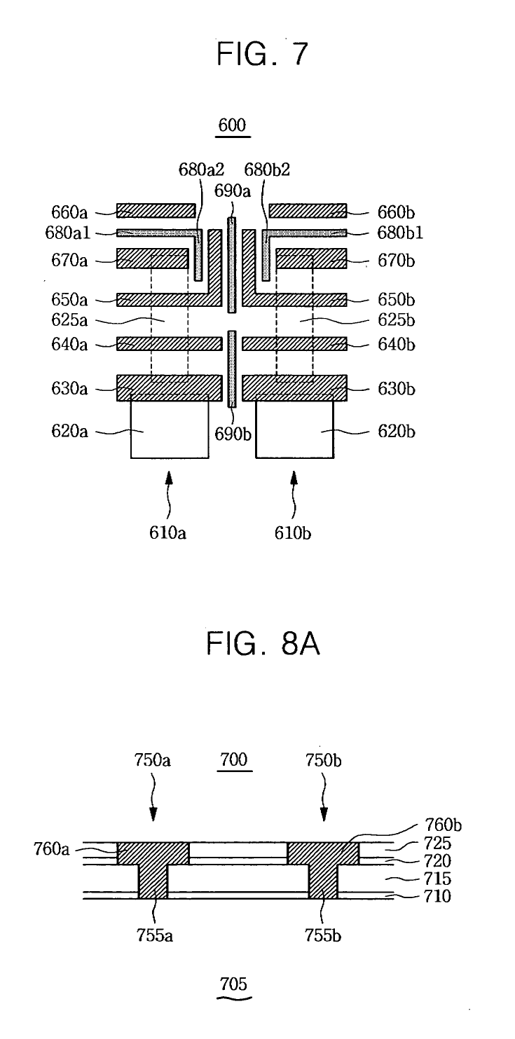

FIGS. 6 and 7 are schematic layouts of complementary metal-oxide-semiconductor (CMOS) image sensors (CIS) according to application further example embodiments of the general inventive concepts.

Referring to FIG. 6, a CMOS image sensor 500 according to a first application example embodiment includes an active pixel sensor 510. The active pixel sensor 510 includes a photo detecting portion 520, at least one voltage supply portion 570, at least one gate structures 540 and 550. Spaces among the elements are filled with any insulating materials. For example, multi-layered insulating materials are formed among the photo detecting portion 520, the voltage supply portion 570, and the gate structures 540 and 550. The multi-layer insulating materials may be the interlayer insulating layers illustrated in FIGS. 1 through 5. The multi-layer insulating material may be the stopper layers illustrated in FIGS. 1 through 5. The multi-layer insulating material may be multi-layered insulator including the interlayer insulating layers and the stopper layers. The shielding walls 580a and 580b may be formed in the insulating materials. The shielding walls 580a and 580b may be formed between one of the voltage supply portion 570 and one of the gate structures 540 and 550. The voltage supply portion 570 includes a via structure for voltage supply, and the gate structures 540 and 550 may include a via structure for gate. One of the gate structures 540 and 550 may be a reset gate structure 540, and the other may be a selection gate structure 550. One of the shielding walls 580a and 580b may be formed between the reset gate structure 540 and the voltage supply portion 570, and the other may be formed between the selection gate structure 550 and the voltage supply portion 570.

The gate structures 540 and 550 included in the active pixel sensor 510 of the CMOS image sensor 500 may include at least one via structure in the active pixel sensor 510. A plurality of voltage supply portions 570 may be provided in the one active pixel sensor 510, and each of the voltage supply portions 570 may include a via structure for voltage supply. For example, the voltage supply portion 570 may be electrically connected to a substrate or a specific gate electrode through the via structure for voltage supply. The specific gate electrode may be one of, for example, a selection gate, a transfer gate, an amplification gate, and a reset gate. The shielding walls 580a and 580b may be formed between the gate structures 540 and 550 or between one of the gate structures 540 and 550 and the voltage supply portion 570.

Referring to FIG. 7, a CMOS image sensor 600 according to a second application example embodiment of the general inventive concepts includes a first active pixel sensor 610a and a second active pixel sensor 610b. The first active pixel sensor 610a includes a first photo detecting portion 620a, a first active region 625a, a first transfer gate structure 630a, a first reset gate structure 640a, a first amplification gate structure 650a, a first selection gate structure 660a, a first voltage supply portion 670a, and first shielding walls 680a1 and 680a2. The second active pixel sensor 610b includes a second photo detecting portion 620b, a second active region 625b, a second transfer gate structure 630b, a second reset gate structure 640b, a second amplification gate structure 650b, a second selection gate structure 660b, a second voltage supply portion 670b, and second shielding walls 680b1 and 680b2. Pixel shielding walls 690a and 690b may be formed between the first active pixel sensor 610a and the second active pixel sensor 610b.

Each of the first and second shielding walls 680a1, 680a2, 680b1 and 680b2 may be formed between one of the gate structures 630a, 630b, 640a, 640b, 650a, 650b, 660a and 660b and one of the voltage supply portions 670a and 670b. The active regions 625a and 625b include floating diffusion regions, which are portions of the active regions 625a and 625b.

In example embodiments, even if electro-migration mainly (or substantially) occurs in interfaces between respective material layers, the interfaces adjacent to a conductor are connected through a long path or spaced apart from each other. Thus, a physical or electrical short circuit is prevented, or the probability of the short circuit is remarkably reduced.

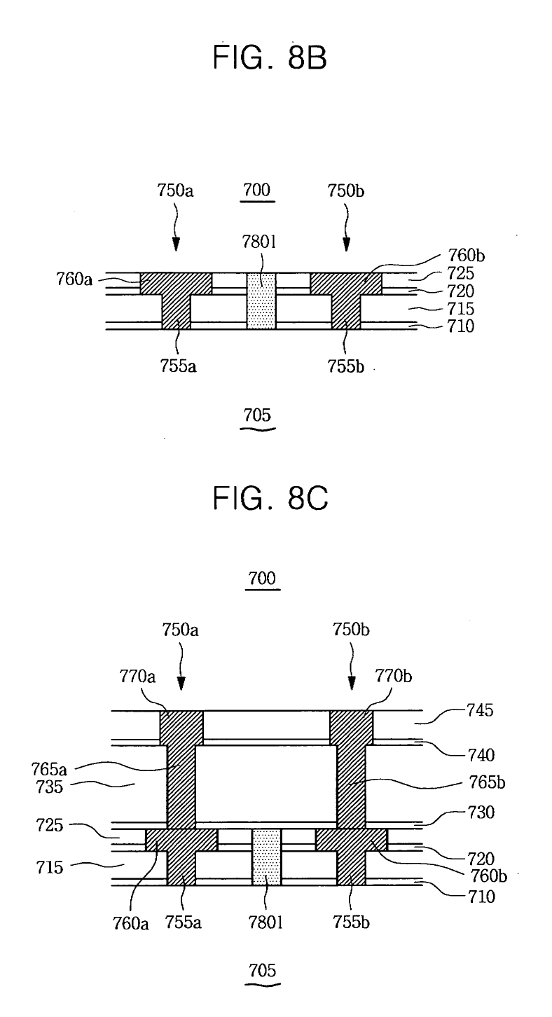

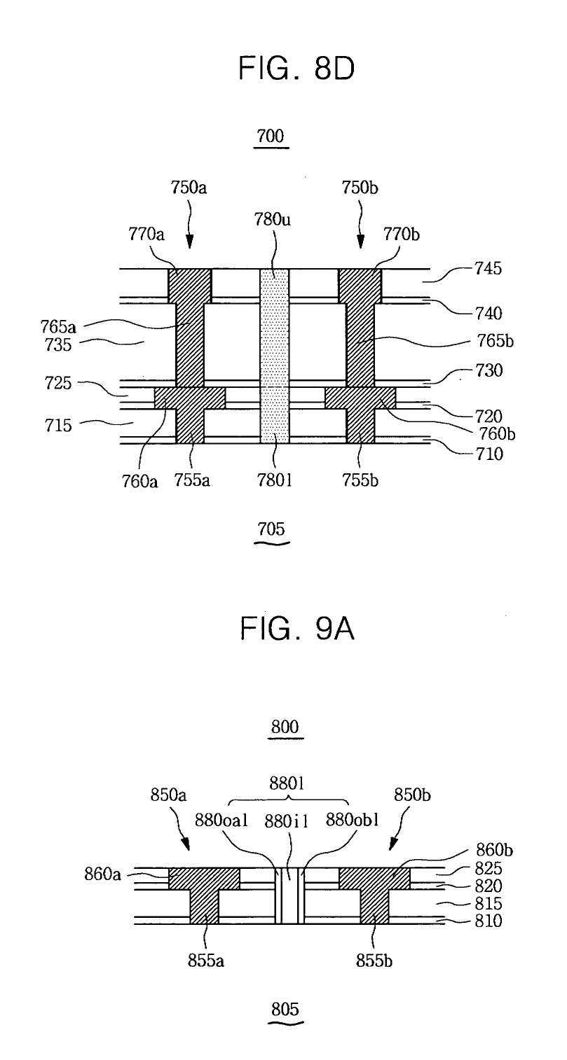

FIGS. 8A to 8D are longitudinal sectional views schematically illustrating a method of fabricating a semiconductor device according to yet other example embodiments.

Referring to FIG. 8A, a first stopper layer 710 is formed on a semiconductor substrate 705, a first interlayer insulating layer 715 is formed on the first stopper layer 710, a second stopper layer 720 is formed on the first interlayer insulating layer 715, a second interlayer insulating layer 725 is formed on the second stopper layer 720, and a lower via 755a and a pad 760a of a first conductor 750a and a lower via 755b and a pad 760b of a second conductor 750b are formed. The lower via 755a of the first conductor 750a and the lower via 755b of the second conductor 750b may penetrate (or extend through) the first stopper layer 710 and the first interlayer insulating layer 715. The pad 760a of the first conductor 750a and the pad 760b of the second conductor 750b may penetrate (or extend through) the second stopper layer 720 and the second interlayer insulating layer 725. The lower vias 755a and 755b and the pads 760a and 760b may be formed by a damascene process, in particular, a dual damascene process. Finally, a chemical mechanical polishing (CMP) process may be performed.

Referring to FIG. 8B, a lower hole is formed through the second interlayer insulating layer 725, the second stopper layer 720, the first interlayer insulating layer 715, and the first stopper layer 710 and filled with an insulating material, thereby forming a lower shielding wall 780l. The lower shielding wall 780l may be formed between the lower via 755a and the pad 760a of the first conductor 750a and the lower via 755b and the pad 760b of the second conductor 750b. Finally, a CMP process may be performed.

Referring to FIG. 8C, a third stopper layer 730 is formed on the second interlayer insulating layer 725 and the pads 760a and 760b, a third interlayer insulating layer 735 is formed on the third stopper layer 730, a fourth stopper layer 740 is formed on the third interlayer insulating layer 735, and a fourth interlayer insulating layer 745 is formed on the fourth stopper layer 740. Subsequently, an upper via 765a of the first conductor 750a and an upper via 765b of the second conductor 750b are formed through the third interlayer insulating layer 735 and the third stopper layer 730. The upper via 765a of the first conductor 750a may be electrically, and/or physically, connected to the pad 760a of the first conductor 750a. The upper via 765b of the second conductor 750b may be electrically, and/or physically, connected to the pad 760b of the second conductor 750b. Subsequently, an interconnection 770a of the first conductor 750a and an interconnection 770b of the second conductor 750b are formed through the fourth interlayer insulating layer 745 and the fourth stopper layer 740. The interconnection 770a of the first conductor 750a may be electrically, and/or physically, connected to the upper via 765a of the first conductor 750a, and the interconnection 770b of the second conductor 750b may be electrically, and/or physically, connected to the upper via 765b of the second conductor 750b. The upper via 765a and the interconnection 770a of the first conductor 750a and the upper via 765b and the interconnection 770b of the second conductor 750b may be formed by one (or the same) dual damascene process. Finally, a CMP process may be performed.

Referring to FIG. 8D, an upper hole is formed through the fourth interlayer insulating layer 745, the fourth stopper layer 740, the third interlayer insulating layer 735, and the third stopper layer 730 and filled with an insulating material, thereby forming an upper shielding wall 780u. The upper shielding layer 780u may be formed between the upper via 765a and the interconnection 770a of the first conductor 750a and the upper via 765b and the interconnection 770b of the second conductor 750b. Finally, a CMP process may be performed. The upper shielding wall 780u may be formed of the same material as the lower shielding wall 7801 and physically connected to the lower shielding wall 7801. A dotted line in the drawing indicates a virtual interface between the lower shielding wall 7801 and the upper shielding wall 780u.

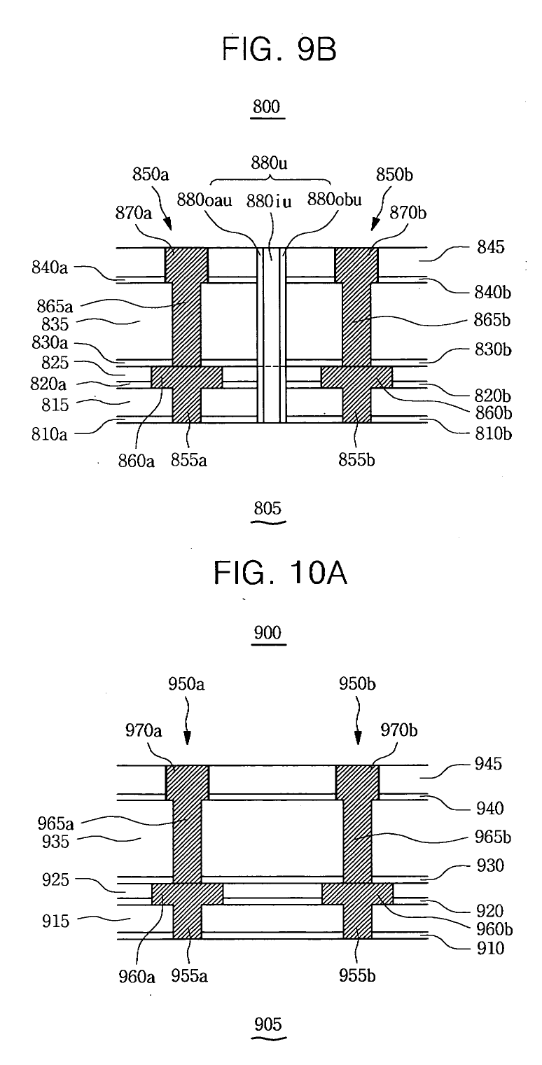

FIGS. 9A and 9B are longitudinal sectional views schematically illustrating methods of fabricating a semiconductor device according to still other example embodiments.

Referring to FIG. 9A, after the operation of FIG. 8A, a lower hole is formed through a second interlayer insulating layer 825, a second stopper layer 820, a first interlayer insulating layer 815, and a first stopper layer 810 and filled with an insulating material, thereby forming a lower shielding wall 880l. The lower shielding wall 880l includes outer shielding walls 880oal and 880obl and an inner shielding wall 880il. Finally, a CMP process may be performed.

Referring to FIG. 9B, a third stopper layer 830, a third interlayer insulating layer 835, a fourth stopper layer 840, and a fourth interlayer insulating layer 845 are formed on the second interlayer insulating layer 825. An upper hole is formed to vertically penetrate (or extend through) the third stopper layer 830, the third interlayer insulating layer 835, the fourth stopper layer 840, and the fourth interlayer insulating layer 845 and expose the lower shielding wall 880l, and filled with an insulating material, thereby forming an upper shielding wall 880u. The upper shielding wall 880u also includes outer shielding walls 880oau and 880obu and an inner shielding wall 880iu. Finally, a CMP process may be performed.

In FIGS. 9A and 9B, the lower and upper outer shielding walls 880oal, 880obl, 880oau and 880obu may be formed of the same material as the stopper layers 810, 820, 830 and 840, and the lower and upper inner shielding walls 880il and 880iu may be formed of the same material as the interlayer insulating layers 815, 825, 835 and 845. A dotted line in the drawing indicates a virtual interface between the lower shielding wall 880l and the upper shielding wall 880u.

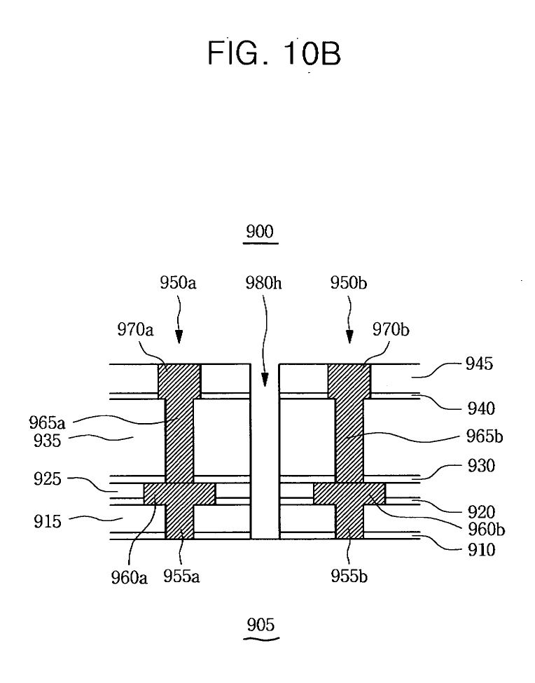

FIGS. 10A and 10B are longitudinal sectional views schematically illustrating a method of fabricating a semiconductor device according to still yet other example embodiments.

Referring to FIG. 10A, on a semiconductor substrate 905, first to fourth stopper layers 910, 920, 930 and 940 and first to fourth interlayer insulating layers 915, 925, 935 and 945 are formed, and a first conductor 950a and a second conductor 950b are formed. The stopper layers 910, 920, 930 and 940 may be formed of silicon nitride, and the interlayer insulating layers 915, 925, 935 and 945 may be formed of silicon oxide. The stopper layers 910, 920, 930 and 940 and the interlayer insulating layers 915, 925, 935 and 945 may be alternately stacked. The first conductor 950a may include a lower via 955a, a pad 960a, an upper via 965a, and an interconnection 970a, and the components may be electrically or physically connected to each other. The second conductor 950b may also include a lower via 955b, a pad 960b, an upper via 965b, and an interconnection 970b, and the components may be electrically or physically connected to each other. The first and second conductors 950a and 950b may be formed to vertically penetrate (or extend through) the first to fourth stopper layers 910, 920, 930 and 940 and the first to fourth interlayer insulating layers 915, 925, 935 and 945.

Referring to FIG. 10B, a shielding hole 980h is formed between the first conductor 950a and the second conductor 950b. The shielding hole 980h may vertically penetrate (or extend through) the first to fourth stopper layers 910, 920, 930 and 940 and the first to fourth interlayer insulating layers 915, 925, 935 and 945. Subsequently, the shielding hole 980h is filled with an insulating material. When the shielding hole 980h is filled with one insulating material, a semiconductor device 900 according to this example embodiment may be formed like the semiconductor device 100 or 200 shown in FIG. 1 or 3. On the other hand, when liner-type outer shielding walls are formed on sidewalls of the shielding wall 980h, the semiconductor device 900 may be formed like the semiconductor device 300 or 400 shown in FIG. 4 or 5.

The above-described example embodiments may not be independently implemented. Characteristics of the example embodiments may be combined with each other to generate new application example embodiments. For example, shielding walls shown in FIGS. 1 and 3 may be combined with shielding walls shown in FIGS. 4 and 5. To be specific, an upper shielding wall may be formed in a different shape from a lower shielding wall. Combinations not mentioned in this specification can be fully understood from the above-described example embodiments.

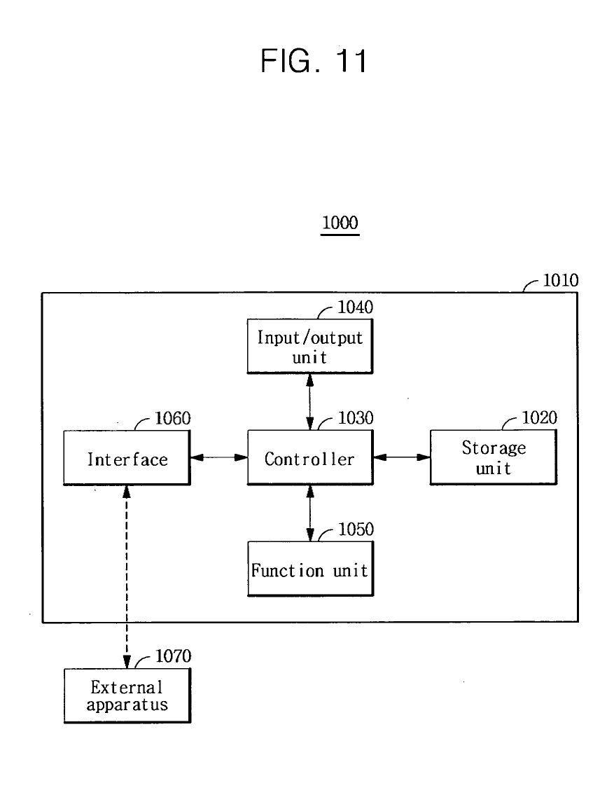

FIG. 11 is a block diagram illustrating an electronic apparatus including the semiconductor device or the CMOS image sensor according to still yet another example embodiment of the general inventive concepts.

Referring to FIG. 11, an electronic apparatus 1000 may include a housing 1010 to accommodate elements or units of the electronic apparatus 1000, a storage unit 1020, a controller 1030, an input/output unit 1040, a function unit 1050, and/or an interface unit 1060 to communicate with an external apparatus 1070 through a wired or wireless communication line to receive and transmit data or signals. At least one of the semiconductor devices in FIGS. 1A through 5 can be used in the storage unit 1020. At least one of the CMOS image sensors in FIGS. 6 and 7 can be used in the function unit 1050. The input/output unit 1040 can be connected to the controller 1030 to receive and/or transmit electronic signals. The electronic signals may be input through the input/output unit 1040, the function unit 1050, and/or the external apparatus 1070 through the interface unit 1060. When the electronic apparatus 1000 is an image processing apparatus, the function unit 1050 may be a camera to take an image. When the electronic apparatus 1000 is a camera or camcorder, the function unit 1050 may be a unit to photograph an image as a movie or a still image. The controller 1030 controls elements and units of the electronic apparatus 1000 or may be a processor. At least one of the semiconductor devices illustrated in FIGS. 1A through 5 can be used in the controller 1030.

As described above, in a semiconductor device according to example embodiments, the lengths of interfaces of insulating layers formed between conductors are increased. Thus, it is possible to prevent, or reduce the likelihood of, problems caused by electro-migration, etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

1. A semiconductor device, comprising:
a semiconductor substrate having a plurality of stopper layers and a plurality of interlayer insulating layers which are alternately stacked, the stopper layers and the interlayer insulating layers being arranged such that interfaces between the stopper layers and the interlayer insulating layers are in a horizontal direction;
a first conductor and a second conductor vertically extend through the interlayer insulating layers and the stopper layers; and
an insulating shielding wall formed between the first and second conductors, the insulating shielding wall vertically extending through the interfaces between the stopper layers and the interlayer insulating layers such that at least one of the interfaces is divided into separate sections.

2. The semiconductor device according to claim 1, wherein each of the first and second conductors includes at least one via.

3. The semiconductor device according to claim 1, wherein the insulating shielding wall and the interlayer insulating layers include a first material.

4. The semiconductor device according to claim 1, wherein the insulating shielding wall vertically extends through the interlayer insulating layers and the stopper layers.

5. The semiconductor device according to claim 3, wherein the interfaces between the stopper layers and the interlayer insulating layers are perpendicular to (i) interfaces between the stopper layers and the insulating shielding wall and (ii) interfaces between the interlayer insulating layers and the insulating shielding wall.

6. The semiconductor device according to claim 5, wherein the insulating shielding wall includes an outer shielding wall and an inner shielding wall, the outer shielding wall and the stopper layers being formed of a second material, and the inner shielding wall and the interlayer insulating layers being formed of the first material.

7. A CMOS image sensor, comprising:
at least two photo detecting portions and at least one voltage supply portion arranged between at least two gate structures;
an insulating material between the voltage supply portion and at least one of the gate structures; and
at least one shielding wall in the insulating material.

8. The CMOS image sensor of claim 7, wherein the insulating material comprises at least one interlayer insulating layer and at least one stopper layer.

9. The CMOS image sensor of claim 8, wherein the interlayer insulating layer includes silicon oxide and the stopper layer includes silicon nitride.

10. The CMOS image sensor of claim 7, wherein the shielding wall vertically extends through the insulating material.

11. The CMOS image sensor of claim 10, wherein the shielding wall comprises a first insulating material.

12. The CMOS image sensor of claim 11, wherein the shielding wall comprises a second insulating material different from the first insulating material, the second insulating material surrounding the first insulating material.

13. A CMOS image sensor, comprising:
a first active pixel sensor over a substrate, the first active pixel sensor including,
a first photo detecting portion,
a first voltage supply portion,
a plurality of first gate structures, and
a first insulating material between the first voltage supply portion and the first gate structures;
a second active pixel sensor adjacent to the first active pixel sensor, the second active pixel sensor including,
a second photo detecting portion,
a second voltage supply portion,
a plurality of second gate structures, and
a second insulating material between the second voltage supply portion and the second gate structures; and
a first shielding wall between the first and second active pixel sensors.

14. The CMOS image sensor of claim 13, wherein the first shielding wall is disposed between the first gate structures and the second gate structures.

15. The CMOS image sensor of claim 14, wherein the first active pixel sensor further includes a first active region,
the second active pixel sensor further includes a second active region, and
a second shielding wall is between the first and second active regions.

16-32. (canceled)
